(19) United States
(12) Patent Application Publication
(10) Pub. No.: US 2019/0379399 A1
(43) Pub. Date: Dec. 12, 2019

(54) LOG-LIKELIHOOD-RATIO (LLR) GENERATION ALGORITHM FOR LOW-DENSITY-PARITY-CHECK (LDPC) CODES USED IN FLASH MEMORY

(71) Applicant: Goke US Research Laboratory, Santa Clara, CA (US)

(72) Inventor: Chandra Varanasi, Santa Clara, CA (US)

(21) Appl. No.: 16/004,273

(22) Filed: Jun. 8, 2018

(51) Int. Cl. H03M 13/11; G06F 11/10; G11C 29/52

(52) U.S. Cl. CPC H03M 13/1125; G06F 11/1068; H03M 13/1108; H03M 13/1148; G11C 29/52

(57) ABSTRACT

Apparatuses and methods suitably configured to utilize at least one algorithm for generating log-likelihood-ratio (LLR) values for low-density-parity-check (LDPC) codes used in flash memory-based systems. Additionally, at least one algorithm sets soft-read thresholds in the memory in such a way as to maximize the mutual information (MI) of the channel created by those thresholds for preventing errors.

### TECHNICAL FIELD

The present invention relates to memory read thresholds, and more particularly, to apparatuses and methods utilizing algorithms for generating log-likelihood-ratio (LLR) values including Low-Density-Parity-Check (LDPC) codes for use in flash memory-based systems to prevent errors.

### BACKGROUND OF THE INVENTION

In flash memory storage devices (such as NAND Flash), information is stored in a cell by different charge levels. During the write and read process, noise is introduced by program disturbance and inter-cell interference charge leakage that causes the voltage level to drop over time, where the drop is proportional to the amount of charge stored as well as the number of solid-state-storage program-erase cycles (“PIE”) a cell has experienced. Since the noise varies across cells, cells intended to be written to the same voltage level exhibit certain voltage distributions when read back. Usually, the distribution from a higher intended voltage level will drift down and broaden as time passes due to the charge leakage effect, potentially overlapping a part of the distribution from a lower intended voltage level. This drifting and broadening phenomenon is more severe for smaller fabrication process nodes. Consequently, discerning cells that belong to a particular distribution becomes increasingly difficult as NAND flash memory vendors aggressively shrink the fabrication process nodes to increase storage density and reduce cost.

When solid state memory (such as NAND Flash) is read, the returned value depends upon a read threshold. For example, in a single level cell (SLC) system where a cell stores a single bit, any cell which has a stored voltage lower than the read threshold is interpreted to store a 1 and any cell which has a stored voltage higher than the read threshold is interpreted to store a 0. The value of this read threshold therefore affects performance of the system. In general, it is desirable to develop techniques which improve the process by which a read threshold is determined and/or inputs which are used to determine a read threshold. Improving a read threshold would, for example, reduce the number of read errors and may enable some codewords (e.g., which are uncorrectable using an error correction code when a less optimal read threshold is used during the read process) to be decoded (e.g., because the reduced number of read errors now falls within the error correction capability of the code).

For hard-read NAND flash memory storage devices, reading back the stored information involves comparing the cell voltage against a set of thresholds. In Single-Level Cell (SLC) devices, the read back value of a bit (either 0 or 1) is solely based on whether the cell voltage is above or below a single threshold. Ideally, the thresholds should be chosen to minimize the number of bit errors due to two potentially overlapping distributions. However, this is not an easy task as the distributions, which are a function of the intended voltage levels, the number of P/E cycles the cells have gone through, and the data retention period (i.e., the period of time elapsed between writing and reading the data), are not known in advance. Hence, setting the thresholds properly to minimize bit error rate (BER) in an adaptive manner is a critical component in ensuring data reliability in modern NAND flash memory storage devices.

The term “hard-read” refers to the fact that the read back values are either 0 or 1. This is in contrast to the term “soft-read”, where the read back values can take on a range of numbers for representing the cell voltage in a fine resolution.

In light of the shortcomings in the prior art, there is definitely a need for error prevention techniques related to read thresholds using algorithms in apparatuses and methods for generating log-likelihood-ratio (LLR) values for Low-Density-Parity-Check (LDPC) codes used in memory systems such as flash memory-based systems.

### SUMMARY OF THE INVENTION

The present invention relates to memory read thresholds.

The present invention further relates to an algorithm for generating log-likelihood-ratio (LLR) values for Low-Density-Parity-Check (LDPC) codes used in flash memory-based systems.

Another aspect of the present invention is to provide an algorithm that sets soft-read thresholds in the memory in such a way as to maximize the mutual information (MI) of the channel 25 created by those thresholds for increasing the reliability of memory such as flash memory.

An additional aspect of the present invention is to provide a system for generating log-likelihood-ratio (LLR) values for low-density-parity-check (LDPC) codes stored on a memory.

In one embodiment, a system is comprised of a low-density-parity-check (LDPC) encoder communicatively coupled to the memory, the memory having a plurality of cells each configured to store at least one data bit; a LDPC decoder communicatively coupled to the memory; a controller 45 having control circuitry communicatively coupled to the LDPC decoder, the controller 45 configured to: generate binary data in the plurality of the cells; write the binary data in the plurality of cells; determine hard-decisions based on a predefined hard-read voltage threshold for each of the plurality of cells; generate soft-read threshold settings; determine probabilities corresponding to each soft-read threshold setting; determine mutual information (MI) for the set of probabilities generated by the soft-read threshold settings; determine the soft-read thresholds that resulted in maximum mutual information (MI); and generate log-likelihood-ratio (LLR) values for the LDPC for the set of soft-read thresholds that maximized the mutual information (MI).

A further embodiment of the present invention provides an apparatus comprised of a memory device having a plurality of cells each configured to store at least one bit; a LDPC encoder communicatively coupled to the memory device; a LDPC decoder communicatively coupled to the memory device; a controller 45 having control circuitry communicatively coupled to a LDPC decoder, the controller 45 configured to: generate binary data in the plurality of the cells; write the binary data in the plurality of cells; generate soft-read threshold settings; determine probabilities corresponding to each soft-read threshold setting; determine mutual information (MI) for the set of probabilities generated by the soft-read threshold settings; determine the soft-read thresholds that resulted in maximum mutual information (MI); and generate log-likelihood-ratio (LLR) values for the LDPC for the set of soft-read thresholds that maximized the mutual information (MI).

Another feature of the present invention is to provide a method for generating log-likelihood-ratio (LLR) values for low-density-parity-check (LDPC) codes stored in memory, the method comprising the steps of: generating binary data in a plurality of cells stored in the memory; writing the binary data in the plurality of cells; determining hard-decisions based on a predefined hard-read voltage threshold for each of the plurality of cells; generating soft-read threshold settings; determining probabilities corresponding to each soft-read threshold setting; determining mutual information (MI) for the set of probabilities generated by the soft-read threshold settings; determining the soft-read thresholds that resulted in maximum mutual (MI) information; and generating log-likelihood-ratio (LLR) values for the LDPC for the set of soft-read thresholds that maximized the mutual information (MI).

For a better understanding of the present invention, its functional advantages and the specific objects attained by its uses, reference should be made to the accompanying drawings, claims and descriptive matter in which there are illustrated embodiments of the invention.

### BRIEF DESCRIPTION OF THE DRAWINGS

FIG. 1 is an illustration of threshold voltage settings used for deciding whether a “1” or “0” is stored in a cell.

FIG. 2 is a communication channel 25 representation of writing data to and reading data from flash memory using read thresholds.

FIG. 3 depicts a graph showing the capacity of an AWGN channel for hard-read, 2-read, 3-read, and full-soft as a function of BER.

FIG. 4 represents an execution diagram for the method of generating log-likelihood-ratio (LLR) values for low-density-parity-check (LDPC) codes stored in memory.

FIG. 5 represents some components of an apparatus in the form of a computing system having at least one memory system, in accordance with one embodiment of the present invention.

FIG. 6 depicts a memory device having a plurality of cells.

### DETAILED DESCRIPTION

The following detailed description is of the best currently contemplated modes of carrying out various embodiments of the invention in which said embodiments can be carried out independently and/or in combination. The description is not to be taken in a limiting sense, but is made for at least the purpose of illustrating the general principles of the invention, since the scope of the invention is best defined by the appended claims.

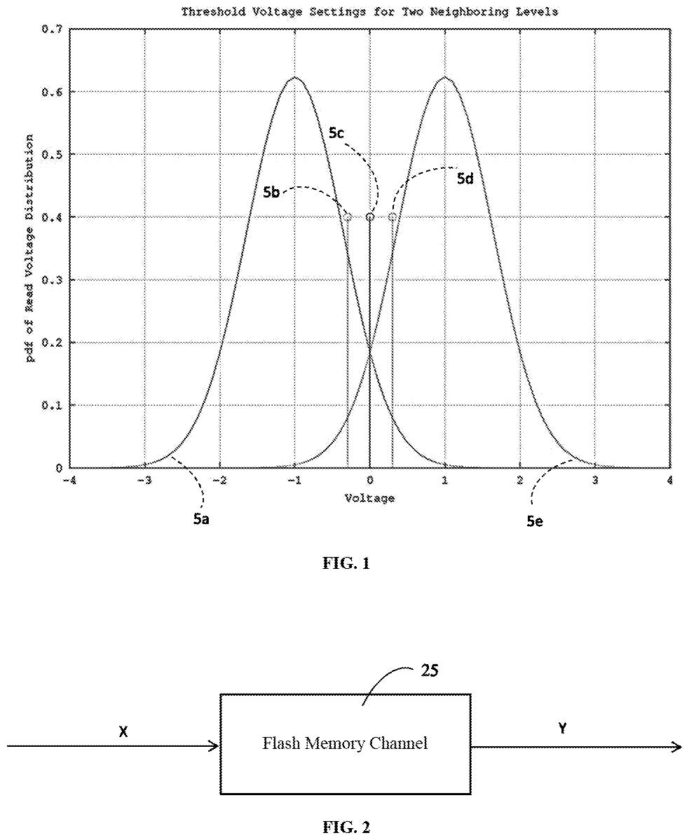

In one embodiment, the distribution of programmed voltages in a flash memory cell 10 can be modeled as Gaussian with the mean centered at the target program voltage. The target program voltage can be mapped for stored bit 1 to −1 and for stored bit 0 to 1. When reading the cell 10, the threshold voltage, Vₜ (5c), is set at the midpoint between the two means—which is 0—and declare the bit stored in the cell to be ‘ 1’ or ‘0’ depending on whether the sensed voltage is below or above the threshold as shown in FIG. 1. In FIG. 1, there are two additional thresholds—shown at 5b and 5a respectively—whose purposes are described later in this disclosure.

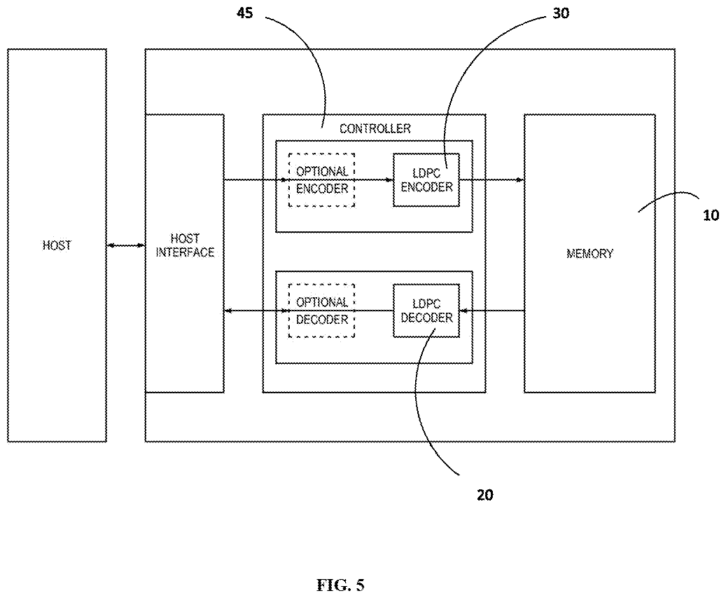

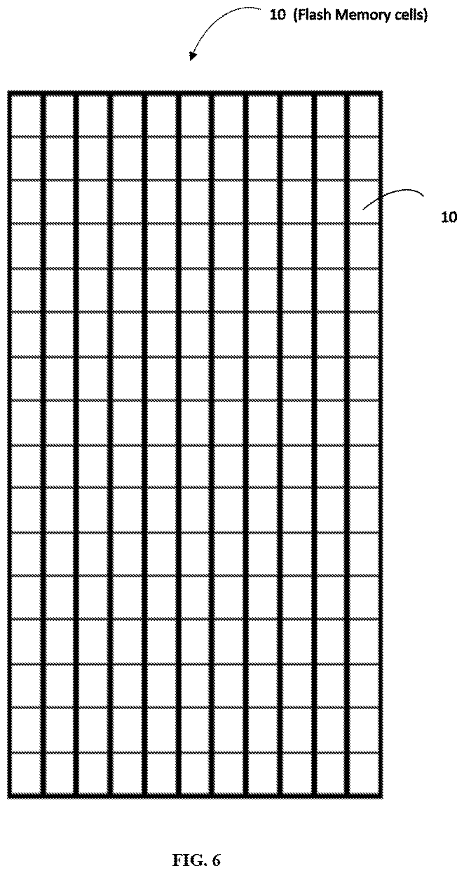

The decision rule described above is useful for making ‘hard’ decisions about the bit stored in the cell 10. For an LDPC decoder 20 (See FIG. 5), the decision rule also needs to supply confidence or reliability information about each decision it made—i.e., the probability (which is a number) that the decision is indeed a 0 or a 1. In another embodiment of the present invention, both the hard decision and the reliability information is combined into one quantity called the log-likelihood-ratio (LLR). If ‘y’ is the decision made and ‘x’ is the bit stored in the cell, LLR(y) is defined as

$$LLR ( y ) = log ( \frac{Pr ( x = 0 \vert y )}{Pr ( x = 1 \vert y )} ) .$$

Bayes's rule can now be used to write the two equations below:

$$Pr ( x = 0 ) Pr ( \frac{y}{x = 0} ) = Pr ( y ) Pr ( \frac{x = 0}{y} )$$

$$Pr ( x = 1 ) Pr ( \frac{y}{x = 1} ) = Pr ( y ) Pr ( \frac{x = 1}{y} )$$

The above two equations can be rearranged as:

$$\frac{Pr ( \frac{x = 0}{y} )}{Pr ( \frac{x = 1}{y} )} = \frac{Pr ( x = 0 )}{Pr ( x = 1 )} \frac{Pr ( \frac{y}{x = 0} )}{Pr ( \frac{y}{x = 1} )}$$

Taking logarithms on both sides equates to:

$$LLR ( y ) = bias term + log ( \frac{Pr ( \frac{y}{x = 0} )}{Pr ( \frac{y}{x = 1} )} )$$

where the bias term is

$$log ( \frac{Pr ( x = 0 )}{Pr ( x = 1 )} ) .$$

In random data, where Pr(x=0)=Pr(x=1)=0.5, the bias term disappears. Even when that is not the case, it is the same for all values of ‘y’ that the random variable Y takes. Hence, it is ignored or added to all of them.

$$LLR ( y ) = log ( \frac{Pr ( \frac{y}{x = 0} )}{Pr ( \frac{y}{x = 1} )} )$$

In a further embodiment, the input random variable X (which takes values from {0,1}) and the output random variable ‘Y’ (which also takes values from {0,1} in the hard-decision case—it takes values from a larger set in ‘soft decision’ case, (which is described later) can also be tied together by another quantity called mutual information I(X;Y) which is defined as follows:

I(X;Y)=H(X)−H(X|Y)

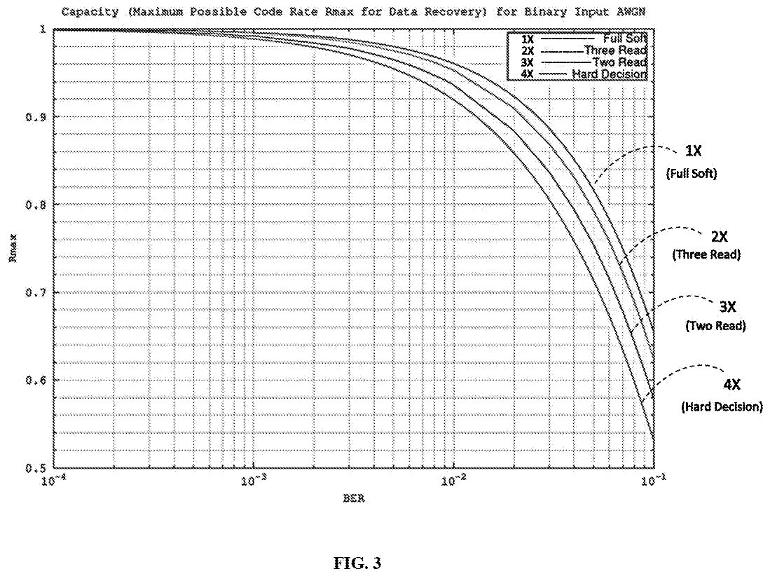

which is identical to I(X; Y)=H(Y)−H(Y|X). Here H(.) is the entropy of the random variable, which is a measure of the uncertainty about what value the random variable takes. Therefore I(X;Y) is the amount of uncertainty in X subtracted by the amount of uncertainty still remaining in X given that Y is known. In other words, it is the amount of information about X conveyed by Y. Obviously, the goal is for output Y to convey maximum information about the input X. The threshold voltages settings should be such that it results in maximum I(X:Y). The maximum I(X;Y) is called the capacity C of the “communication channel” 25 created by those threshold settings (See FIG. 2) and for the LDPC code (or any other code, for that matter) to succeed, its code rate R should be below C. For this reason, C is also referred to as the maximum possible code Rate Rₘₐₓ. LLR values should now be computed for those setting of thresholds. Procedures for the ‘hard decision’ case as well as a ‘soft decision’ case are described.

Computations of I(X;Y) and LLRs make use of the same quantities. This becomes evident once the computation of I(X;Y) is described.

$$I ( X ; Y ) = H ( Y ) - H ( Y \vert X )$$

$$H ( Y ) = - {\sum }_{i = 1}^{n} Pr ( Y = {y}_{i} ) {log}_{2} ( Pr ( Y = {y}_{i} ) )$$

$$H ( Y \vert X ) = {\sum }_{i = 1}^{m} Pr ( X = {x}_{i} ) H ( Y \vert X = {x}_{i} )$$

In the above formulas, X is the input bit written. So, it takes two values: X=0 and X=1. The same formula used for H(Y) can be used to compute H(Y|X=xᵢ) for each xᵢ in computing H(YIX) by considering only the values of Y that resulted when X=xᵢ was written. Y is the output sense voltage (shown as the x-axis in FIG. 1). For hard decisions, only one threshold is set as shown in FIG. 1, the boundary line 5c shown at voltage=0. This threshold splits the entire x-axis (i.e., voltage axis) into two bins: one bin—bin 1—to the left of the threshold, or all the sense voltages<0, and another bin—bin 2—to the right of the threshold defining all voltages>=0. Therefore, Y takes two values: Y={Bin 1, Bin 2} and |Y|=2.

For soft-reads (i.e., more than one read) the granularity of the voltage axis is increased. Besides the hard-read, if a 2^{nd} threshold is set that is denoted by line 5a and do an additional read, this generates three bins for the random variable Y: one bin—bin1—to the left of the 1^{st} threshold representing all negative voltages, bin 2 representing all sense voltages that lie between the 1st threshold and the 2^{nd} threshold, bin 3 representing all the sense voltages greater than the 2^{nd} threshold. Therefore, Y={Bin1, Bin 2, Bin 3} and |Y|=3.

If an additional read is performed by setting a 3rd threshold at the boundary indicated by line 5b, four possible values are created, or bins, for the random variable Y: bin 1 representing all the voltage values to the left of the 3^{rd} threshold, bin 2 representing all the values between the 3^{rd} and the 1^{st} threshold, bin 3 representing all the values between the 1^{st} and the 2nd threshold, and bin 4 representing all the voltages to the right of the 2^{nd} threshold. Therefore, Y={Bin1, Bin2, Bin3, Bin4} and |Y|=4.

Optionally, the granularity of the voltage axis can be increased—or in other words, IYI, the number of values that Y can assume—by doing additional reads. In the limiting case of infinite reads, the ‘full soft’ case of Y being the analog sense voltage itself is obtained. This case sets the upper limit on the mutual information I(X;Y). The more the granularity of Y, the closer it gets to this upper limit.

When the equations for LLR above was described, it did not specify the range of values Y takes and left it as a generic value ‘y.’ The equations for LLR can be re-written when Y takes a value from the set Y={bin1, Bin2, Bin3, . . . , bin N} where N is the number of distinct bins, which in turn, equals (number of reads+1).

$$LLR ( Y = Bin 1 ) = log ( \frac{Pr ( \frac{Y = Bin 1}{X = 0} )}{Pr ( \frac{Y = Bin 1}{X = 1} )} )$$

$$LLR ( Y = Bin 2 ) = log ( \frac{Pr ( \frac{Y = Bin 2}{X = 0} )}{Pr ( \frac{Y = Bin 2}{X = 1} )} )$$

$$LLR ( Y = Bin 3 ) = log ( \frac{Pr ( \frac{Y = Bin 3}{X = 0} )}{Pr ( \frac{Y = Bin 3}{X = 1} )} )$$

$$LLR ( Y = Bin 4 ) = log ( \frac{Pr ( \frac{Y = Bin 4}{X = 0} )}{Pr ( \frac{Y = Bin 4}{X = 1} )} )$$

All the probabilities in the above formulas can be numerically computed by writing random binary data and obtaining the counts for each of the bins for both X=0 and X=1. Pictorially, the entries can be entered in the tables below:

TABLE 1
Hard Read Situation

| | |
|---|---|
| Bit Written | Counts of Y |

| | | | |
|---|---|---|---|
| (X) | Counts of X | Bin 1\|X | Bin 2\|X |

X = 0
X = 1
Totals

TABLE 2
2-Read Situation

| | |
|---|---|
| Bit Written | Counts of Y |

| | | | | |
|---|---|---|---|---|
| (X) | Counts | Bin 1\|X | Bin 2\|X | Bin 3\|X |

X = 0
X = 1
Totals

TABLE 3
3-Read Situation

| Bit Written | | Counts of Y | | | |
|---|---|---|---|---|---|
| (X) | Counts of X | Bin 1\|X | Bin 2\|X | Bin 3\|X | Bin 4\|X |
| X = 0 | | | | | |
| X = 1 | | | | | |
| Totals | | | | | |

$$Then P ( Y = Bin 1 \vert X = 0 ) = \frac{Count of Bin 1 \vert X = 0}{Count of X = 0}$$

$$P ( Y = Bin 1 \vert X = 1 ) = \frac{Count of Bin 1 \vert X = 1}{Count of X = 1}$$

$$P ( Y = Bin 2 \vert X = 0 ) = \frac{Count of Bin 2 \vert X = 0}{Count of X = 0}$$

$$P ( Y = Bin 2 \vert X = 1 ) = \frac{Count of Bin 2 \vert X = 1}{Count of X = 1}$$

$$P ( Y = Bin 3 \vert X = 0 ) = \frac{Count of Bin 3 \vert X = 0}{Count of X = 0}$$

$$( Y = Bin 3 \vert X = 1 ) = \frac{Count of Bin 3 \vert X = 1}{Count of X = 1}$$

$$P ( Y = Bin 4 \vert X = 0 ) = \frac{Count of Bin 4 \vert X = 0}{Count of X = 0}$$

$$P ( Y = Bin 4 \vert X = 0 ) = \frac{Count of Bin 4 \vert X = 0}{Count of X = 0}$$

$$Total Y Counts = Total Bin 1 \vert X counts + Total Bin 2 \vert X counts + Total Bin 3 \vert X counts + Total Bin 4 \vert X counts$$

$$P ( Y = Bin 1 ) = \frac{Total of Bin 1 \vert X counts}{Total of Y Counts}$$

$$P ( Y = Bin 2 ) = \frac{Total of Bin 2 \vert X counts}{Total of Y Counts}$$

$$P ( Y = Bin 3 ) = \frac{Total of Bin 3 \vert X counts}{Total of Y Counts}$$

$$P ( Y = Bin 4 ) = \frac{Total of Bin 4 \vert X counts}{Total of Y Counts}$$

$$P ( X = 0 ) = \frac{Counts of X = 0}{Counts of X = 0 + Counts of X = 1}$$

$$P ( X = 1 ) = \frac{Counts of X = 1}{Counts of X = 0 + Counts of X = 1}$$

In another embodiment, total y counts are calculated as follows:

$$Total Y Counts = Total Bin 1 + Total Bin 2 + Total Bin 3 + Total BinN$$

$$P ( Y = Bin 1 ) = \frac{Total Bin}{Total Y Counts}$$

$$P ( Y = Bin 2 ) = \frac{Total Bin 2}{Total Y Counts}$$

$$P ( Y = Bin 3 ) = \frac{Total Bin 3}{Total Y Counts}$$

$$P ( Y = BinN ) = \frac{Total BinN}{Total Y Counts}$$

$$P ( X = 0 ) = \frac{Counts of X = 0}{Counts of X = 0 + Counts of X = 1}$$

$$P ( X = 1 ) = \frac{Counts of X = 1}{Counts of X = 0 + Counts of X = 1}$$

Algorithm to Generate LLRs for LDPC Decoder:
1. Generate random binary data worth a Block (or some number of blocks) and write it on Flash at conditions that would generate the desired Bit Error Rate (BER) ‘p’.
2. Begin with the best hard-read threshold. Fill the counts in Table 1.
3. For the 2-read situation, sweep a range of 2^{nd} thresholds in some pre-defined increments—say, 0.1 V—away from the hard-read threshold, and for each such setting fill in the counts in Table 2.
4. Using those counts, compute the probabilities Pr(X=0), Pr(X=1), Pr(Y=Bin1|X=0), Pr(Y=Bin1|X=1), Pr(Y=Bin2|X=0), Pr(Y=Bin2|X=1), Pr(Y=Bin1), PrY=(Bin2).
5. Using the formula for MI, compute MI from those probabilities.
6. Choose that 2^{nd} read threshold setting that resulted in the maximum MI among all those MI values.
7. For that MI-maximizing 2^{nd} read threshold setting, compute LLRs as described above.
8. Keeping that best 2^{nd}-read threshold, sweep a range of 3^{rd}-read thresholds and fill the entries in Table 3 for each such setting. Using those entries, compute Pr(Y=Bin1), Pr(Y=Bin2), Pr(Y=Bin3), Pr(Y=Bin1|X=0), Pr(Y=Bin1|X=1), Pr(Y=Bin2|X=0), Pr(Y=Bin2|X=1), Pr(Y=Bin3|X=0), Pr(Y=Bin3|X=1).
9. Compute the 3-read MI for each such setting and pick the one that yields the maximum MI.
10. For that setting, compute LLRs as described above.

Most of the information between X and Y is captured after three reads. In other words, I(X;Y) after three reads gets close to the case of ‘full-soft’ or ‘infinite-number-of-reads’ situation. The MI for hard-read 4X, two-read 2X, three-read 3X, and full-soft 1X cases are shown in FIG. 3. The values of MI for full-soft 1X are calculated using an analytical formula whereas for 2-read and 3-read situations, they were computed using the algorithmic procedure described above. The farther the code rate R is from capacity C, the easier it is for the code to succeed. If a code of rate R does not succeed with the hard-read, then the best 2-read setting is decoded since C for 2-read is higher than the hard-read, and if that fails, then the best 3-read setting is decoded since that increases the capacity even more. (See FIG. 3). It is clear from FIG. 3 that no additional benefit is derived from multiple-reads when the BER is good. Only as the BER worsens, will soft-reads need to be obtained.

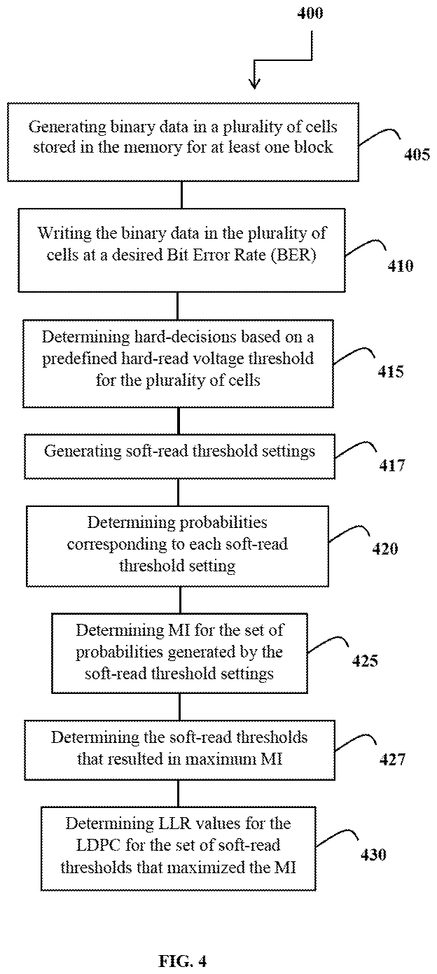

As shown in FIG. 4, a method 400 of the present invention advantageously includes steps to generate log-likelihood-ratio (LLR) values for low-density-parity-check (LDPC) codes stored in memory. For instance, at block 405, the method comprises the step of generating binary data in a plurality of cells stored in the memory for at least one block.

At block 410, the method comprises the step of writing the binary data in the plurality of cells.

At block 415, the method comprises the step of determining hard-decisions based on a predefined hard-read voltage threshold for the plurality of cells.

At block 417, the method comprises the step of generating soft-read threshold settings.

At block 420, the method comprises the step of determining probabilities corresponding to each soft-read threshold setting.

At block 425, the method comprises the step of determining mutual information for the set of probabilities generated by the soft-read threshold settings.

At block 427, the method comprises the step of determining the soft-read thresholds that resulted in maximum MI.

At block 430, the method comprises the step of determining LLR values for the LDPC for the set of soft-read thresholds that maximized the MI.

In one embodiment, a slight modification is done to the above algorithm. In soft-read situations, the assignment of bins in Y depend on which range of analog values Y takes. In other embodiments, there is no access to that analog voltage in practice. Only thresholds are set and the range of analog voltage values that Y belongs to are determined. For each threshold, the decision rule is the same: if ‘Y’ is to the left of the threshold, the decision about X is a “1”, and if it is to the right of the threshold, the decision about X is a “0”. Therefore, a look-up table as shown in Table 4 and Table 5 is used for capturing the best situation in the assignment of analog voltage ranges of Y to the corresponding bins. The assignment in Table 4 uses the following logic: if both the hard read and the 2^{nd} read result in X=0 decisions, Y belongs to Bin 3. If both decisions are X=1, Y is assigned Bin 1. If both decisions are not the same, Y is assigned Bin 2.

In Table 5, the following logic is used: if all three reads yield X=0 decision, then Y is given Bin 4, if two out of three decisions give us X=0 decision, Y is assigned Bin 3. Similarly, if all three thresholds yield X=1 decision, Y is allocated to Bin 1, and, finally, if two out of three thresholds result in X=1 decision, Y is assigned to Bin 2.

TABLE 4
Assignment of Bins in Y for 2-Read Situation

| | 1^{st} Read Threshold | 2^{nd} Read | |
|---|---|---|---|
| | Decision (Hard | Threshold | Assignment |
| Bit Written X | Read) | Decision | of Bin in Y |
| 0 | 0 | 0 | 3 |
| 0 | 0 | 1 | 2 |
| 0 | 1 | 0 | 2 |
| 0 | 1 | 1 | 1 |
| 1 | 0 | 0 | 3 |
| 1 | 0 | 1 | 2 |
| 1 | 1 | 0 | 2 |
| 1 | 1 | 1 | 1 |

TABLE 5
Assignment of Bins in Y for the 3-Read Case

| Bit | Hard | 2^{nd} Read | 3^{rd} Read | Bin |
|---|---|---|---|---|
| Written X | Read Decision | Decision | Decision | Assignment in Y |
| 0 | 0 | 0 | 0 | 4 |
| 0 | 0 | 0 | 1 | 3 |
| 0 | 0 | 1 | 0 | 3 |
| 0 | 0 | 1 | 1 | 2 |
| 0 | 1 | 0 | 0 | 3 |
| 0 | 1 | 0 | 0 | 3 |
| 0 | 1 | 1 | 0 | 2 |
| 0 | 1 | 1 | 1 | 1 |
| 1 | 0 | 0 | 0 | 4 |
| 1 | 0 | 0 | 1 | 3 |
| 1 | 0 | 1 | 0 | 3 |
| 1 | 0 | 1 | 1 | 2 |
| 1 | 1 | 0 | 0 | 3 |
| 1 | 1 | 0 | 1 | 2 |
| 1 | 1 | 1 | 0 | 2 |
| 1 | 1 | 1 | 1 | 1 |

TABLE 6
Output of LLR Generation Algorithm from RBER ranging from 1e−3 to 1e−1

| | | | | | LLR Values | | | | | | | | |
|---|---|---|---|---|---|---|---|---|---|---|---|---|---|
| | Mutual Information (MI) | | | | Hard Read | | 2-Read | | | 3-Read | | | |
| BER | MI | MI2 | MI3 | MIF | LLR0 | LLR1 | LRB1 | LLRB2 | LLRB3 | LLRB1 | LLRB2 | LLRB3 | LLRB4 |
| 1e−3 | 0.989 | 0.992 | 0.995 | 0.996 | 6.9 | −6.9 | −6.9 | 1.85 | 9.14 | −9.13 | −1.86 | 1.85 | 9.14 |
| 2e−3 | 0.979 | 0.984 | 0.990 | 0.992 | 6.2 | −6.2 | −6.2 | 1.6 | 8.2 | −8.18 | −1.62 | 1.6 | 8.2 |
| 3e−3 | 0.971 | 0.978 | 0.985 | 0.988 | 5.8 | −5.8 | −5.8 | 1.48 | 7.6 | −7.6 | −1.47 | 1.48 | 7.61 |
| 4e−3 | 0.962 | 0.971 | 0.980 | 0.984 | 5.5 | −5.5 | −5.5 | 2.01 | 8.15 | −8.14 | −2 | 2 | 8.15 |
| 5e−3 | 0.955 | 0.965 | 0.975 | 0.980 | 5.3 | −5.3 | −5.3 | 1.9 | 7.79 | −7.8 | −1.9 | 1.9 | 7.8 |
| 6e−3 | 0.947 | 0.959 | 0.971 | 0.976 | 5.1 | −5.1 | −5.1 | 1.8 | 7.47 | −7.46 | −1.81 | 1.81 | 7.47 |
| 7e−3 | 0.940 | 0.953 | 0.966 | 0.972 | 4.96 | −4.96 | −4.95 | 1.74 | 7.22 | −7.21 | −1.73 | 1.74 | 7.22 |
| 8e−3 | 0.933 | 0.947 | 0.962 | 0.968 | 4.82 | −4.82 | −4.82 | 1.68 | 7.01 | −7 | −1.67 | 1.68 | 7.01 |
| 9e−3 | 0.926 | 0.941 | 0.957 | 0.964 | 4.7 | −4.7 | −4.7 | 1.62 | 6.8 | −6.8 | −1.61 | 1.62 | 6.8 |
| 1e−2 | 0.919 | 0.936 | 0.953 | 0.961 | 4.59 | −4.59 | −4.6 | 1.56 | 6.63 | −6.64 | −1.56 | 1.56 | 6.63 |
| 2e−2 | 0.859 | 0.884 | 0.910 | 0.923 | 3.89 | −3.89 | −3.89 | 1.6 | 6.09 | −6.08 | −1.6 | 1.6 | 6.09 |
| 3e−2 | 0.806 | 0.837 | 0.869 | 0.887 | 3.47 | −3.47 | −3.47 | 1.35 | 5.33 | −5.32 | −1.35 | 1.35 | 5.33 |
| 4e−2 | 0.758 | 0.794 | 0.831 | 0.851 | 3.18 | −3.18 | −3.18 | 1.18 | 4.79 | −4.79 | −1.18 | 1.18 | 4.79 |
| 5e−2 | 0.714 | 0.754 | 0.793 | 0.816 | 2.95 | −2.95 | −2.94 | 1.28 | 4.76 | −4.76 | −1.28 | 1.28 | 4.76 |
| 6e−2 | 0.673 | 0.715 | 0.758 | 0.783 | 2.75 | −2.75 | −2.75 | 1.15 | 4.38 | −4.37 | −1.15 | 1.15 | 4.38 |
| 7e−2 | 0.634 | 0.678 | 0.722 | 0.750 | 2.59 | −2.59 | −2.59 | 1.04 | 4.05 | −4.05 | −1.04 | 1.04 | 4.05 |
| 8e−2 | 0.598 | 0.643 | 0.689 | 0.717 | 2.44 | −2.44 | −2.44 | 1.12 | 4.06 | −4.06 | −1.12 | 1.12 | 4.06 |
| 9e−2 | 0.564 | 0.610 | 0.656 | 0.685 | 2.31 | −2.31 | −2.31 | 1.02 | 3.78 | −3.79 | −1.02 | 1.02 | 3.78 |
| 1e−1 | 0.531 | 0.578 | 0.624 | 0.654 | 2.2 | −2.2 | −2.2 | 0.94 | 3.54 | −3.54 | −0.94 | 0.94 | 3.54 |

It should be understood that the foregoing relates to various embodiments of the present invention which can be carried out independently and/or in combination and that modifications may be made without departing from the spirit and scope of the invention. It should be further understood that the present invention is not limited to the designs mentioned in this application and the equivalent designs in this description, but it is also intended to cover other equivalents now known to those skilled in the art, or those equivalents which may become known to those skilled in the art in the future.

### INDUSTRIAL APPLICABILITY

The present invention pertains to an algorithm for generating log-likelihood-ratio (LLR) values for Low-Density-Parity-Check (LDPC) codes used in flash memory-based systems, which may be of value or importance to various industries, such as the semiconductor industry.

What is claimed is:

1. A system for generating log-likelihood-ratio (LLR) values for low-density-parity-check (LDPC) codes stored on a memory, comprising;
a low-density-parity-check (LDPC) encoder communicatively coupled to the memory, the memory having a plurality of cells each configured to store at least one data bit;
a LDPC decoder communicatively coupled to the memory;
a controller having control circuitry communicatively coupled to the LDPC decoder, the controller configured to:
generate binary data in the plurality of the cells;
write the binary data in the plurality of cells;
determine hard-decisions based on a predefined hard-read voltage threshold for each of the plurality of cells;
generate soft-read threshold settings;
determine probabilities corresponding to each soft-read threshold setting;
determine mutual information (MI) for the set of probabilities generated by the soft-read threshold settings;
determine the soft-read thresholds that resulted in maximum mutual information (MI); and
generate log-likelihood-ratio (LLR) values for the LDPC for the set of soft-read thresholds that maximized the mutual information (MI).

2. The system according to claim 1, wherein the mutual information (MI) is determined by the following first equation:
$$I ( X ; Y ) = H ( Y ) - H ( Y \vert X )$$
$$H ( Y ) = - {\sum }_{i = 1}^{n} Pr ( Y = {y}_{i} ) {log}_{2} ( Pr ( Y = {y}_{i} ) )$$
$$H ( Y \vert X ) = {\sum }_{i = 1}^{m} Pr ( X = {x}_{i} ) H ( Y \vert X = {x}_{i} )$$
where X is the input bit, Y is the output sense voltage, H is the entropy of the random variable, and Pr is a probability that ‘Y’ is ‘1’ or ‘0’

3. The system according to claim 1, wherein the log-likelihood-ratio (LLR) values are determined by the following second equation:
$$P ( Y = Bin 1 ) = \frac{Total Bin 1}{Total Y Counts}$$
$$P ( Y = Bin 2 ) = \frac{Total Bin 2}{Total Y Counts}$$
$$P ( Y = Bin 3 ) = \frac{Total Bin 3}{Total Y Counts}$$
$$P ( Y = BinN ) = \frac{Total BinN}{Total Y Counts}$$
$$P ( X = 0 ) = \frac{Counts of X = 0}{Counts of X = 0 + Counts of X = 1}$$
$$P ( X = 1 ) = \frac{Counts of X = 1}{Counts of X = 0 + Counts of X = 1}$$
where Y takes a value from the set Y={bin 1, bin2, bin3, . . . , bin N} where N is the number of distinct bins, which in turn, equal (number of reads+1).

4. The system according to claim 1, wherein the generated binary data in the plurality of the cells is generated for at least one block.

5. The system according to claim 1, wherein the binary data is written in the plurality of cells at a desired Bit Error Rate (BER).

6. The system according to claim 2, wherein the first equation maximizes the mutual information (MI) of the communication channel created by the soft-read thresholds in the memory such that the code rate of the LDPC is below the maximum MI of said communication channel for preventing errors.

7. The system according to claim 1, wherein the memory is flash memory.

8. An apparatus comprising;
a memory device having a plurality of cells each configured to store at least one bit;
a LDPC encoder communicatively coupled to the memory device;
a LDPC decoder communicatively coupled to the memory device;
a controller having control circuitry communicatively coupled to a LDPC decoder, the controller configured to:
generate binary data in the plurality of the cells;
write the binary data in the plurality of cells;
generate soft-read threshold settings;
determine probabilities corresponding to each soft-read threshold setting;
determine mutual information (MI) for the set of probabilities generated by the soft-read threshold settings;
determine the soft-read thresholds that resulted in maximum mutual information (MI); and
generate log-likelihood-ratio (LLR) values for the LDPC for the set of soft-read thresholds that maximized the mutual information (MI).

9. The apparatus according to claim 8, wherein the controller is further configured to:
determine hard-decisions based on a predefined hard-read voltage threshold for the plurality of cells.

10. The apparatus according to claim 9, wherein the mutual information (MI) is determined by the following first equation:
$$I ( X ; Y ) = H ( Y ) - H ( Y \vert X )$$
$$H ( Y ) = - {\sum }_{i = 1}^{n} Pr ( Y = {y}_{i} ) {log}_{2} ( Pr ( Y = {y}_{i} ) )$$
$$H ( Y \vert X ) = {\sum }_{i = 1}^{m} Pr ( X = {x}_{i} ) H ( Y \vert X = {x}_{i} )$$
where X is the input bit, Y is the output sense voltage, H is the entropy of the random variable, and Pr is a probability that ‘Y’ is ‘1’ or ‘0’

11. The apparatus according to claim 9, wherein the log-likelihood-ratio (LLR) values are determined by the following second equation:
$$P ( Y = Bin 1 ) = \frac{Total Bin 1}{Total Y Counts}$$
$$P ( Y = Bin 2 ) = \frac{Total Bin 2}{Total Y Counts}$$
$$P ( Y = Bin 3 ) = \frac{Total Bin 3}{Total Y Counts}$$
$$P ( Y = BinN ) = \frac{Total BinN}{Total Y Counts}$$
$$P ( X = 0 ) = \frac{Counts of X = 0}{Counts of X = 0 + Counts of X = 1}$$
$$P ( X = 1 ) = \frac{Counts of X = 1}{Counts of X = 0 + Counts of X = 1}$$
where Y takes a value from the set Y={bin 1, bin2, bin3, . . . , bin N} where N is the number of distinct bins, which in turn, equal (number of reads+1).

12. The apparatus according to claim 8, wherein the generated binary data in the plurality of the cells is generated for at least one block, and wherein the binary data is written in the plurality of cells at a desired Bit Error Rate (BER).

13. The apparatus according to claim 10, wherein the first equation maximizes the mutual information (MI) of the communication channel created by the soft-read thresholds in the memory such that the code rate of the LDPC is below the maximum MI of said communication channel for preventing errors.

14. The apparatus according to claim 8, wherein the memory is flash memory.

15. A method for generating log-likelihood-ratio (LLR) values for low-density-parity-check (LDPC) codes stored in memory, the method comprising the steps of:
generating binary data in a plurality of cells stored in the memory;
writing the binary data in the plurality of cells;
determining hard-decisions based on a predefined hard-read voltage threshold for each of the plurality of cells;
generating soft-read threshold settings;
determining probabilities corresponding to each soft-read threshold setting;
determining mutual information (MI) for the set of probabilities generated by the soft-read threshold settings;
determining the soft-read thresholds that resulted in maximum mutual (MI) information; and
generating log-likelihood-ratio (LLR) values for the LDPC for the set of soft-read thresholds that maximized the mutual information (MI).

16. The method according to claim 15, wherein the mutual information (MI) is determined by the following first equation:
$$I ( X ; Y ) = H ( Y ) - H ( Y \vert X )$$
$$H ( Y ) = - {\sum }_{i = 1}^{n} Pr ( Y = {y}_{i} ) {log}_{2} ( Pr ( Y = {y}_{i} ) )$$
$$H ( Y \vert X ) = {\sum }_{i = 1}^{m} Pr ( X = {x}_{i} ) H ( Y \vert X = {x}_{i} )$$
where X is the input bit, Y is the output sense voltage, H is the entropy of the random variable, and Pr is a probability that ‘Y’ is ‘1’ or ‘0’

17. The method according to claim 16, wherein the log-likelihood-ratio (LLR) values are determined by the following second equation:
$$P ( Y = Bin 1 ) = \frac{Total Bin 1}{Total Y Counts}$$
$$P ( Y = Bin 2 ) = \frac{Total Bin 2}{Total Y Counts}$$
$$P ( Y = Bin 3 ) = \frac{Total Bin 3}{Total Y Counts}$$
$$P ( Y = BinN ) = \frac{Total BinN}{Total Y Counts}$$
$$P ( X = 0 ) = \frac{Counts of X = 0}{Counts of X = 0 + Counts of X = 1}$$
$$P ( X = 1 ) = \frac{Counts of X = 1}{Counts of X = 0 + Counts of X = 1}$$
where Y takes a value from the set Y={bin 1, bin2, bin3, . . . , bin N} where N is the number of distinct bins, which in turn, equal (number of reads+1).

18. The method according to claim 15, wherein the generated binary data in the plurality of the cells is generated for at least one block.

19. The method according to claim 15, wherein the binary data is written in the plurality of cells at a desired Bit Error Rate (BER) and, wherein the memory is flash memory.

20. The method according to claim 16, wherein the first equation maximizes the mutual information (MI) of the communication channel created by the soft-read thresholds in the memory such that the code rate of the LDPC is below the maximum MI of said communication channel for preventing errors.
